(19) United States
(12) Patent Application Publication
(10) Pub. No.: US 2026/0136554 A1
(43) Pub. Date: May 14, 2026

(54) SEMICONDUCTOR MEMORY DEVICES AND ELECTRONIC SYSTEMS INCLUDING THE SAME

(71) Applicant: Samsung Electronics Co., Ltd., Suwon-si (KR)

(72) Inventors: Young Woo KIM, Suwon-si (KR); Ji Man HONG, Suwon-si (KR); Byoung-Taek KIM, Suwon-si (KR); Young In CHO, Suwon-si (KR)

(21) Appl. No.: 19/278,878

(22) Filed: Jul. 24, 2025

(30) Foreign Application Priority Data
Nov. 14, 2024 (KR) 10-2024-0161806

(51) Int. Cl. H10B 43/27; G11C 5/06; G11C 16/04; H01L 23/00; H01L 25/18; H10B 43/35; H10B 43/40; H10B 80/00; H10D 80/30

(52) U.S. Cl. CPC H10B 43/27; G11C 5/063; G11C 16/0483; H10B 43/35; H10B 43/40; H10B 80/00; H10D 80/30; H10W 90/00; H10W 90/20; H10W 90/732; H10W 90/734; H10W 90/792

(57) ABSTRACT

A semiconductor memory device includes a substrate including first, second, and third regions, wherein the second region is adjacent the first and third regions; a first mold structure including insulating layers and gate electrode layers on the substrate in the first region; a second mold structure on the substrate in the second region; a third mold structure on the substrate in the third region; a channel structure in the first mold structure; a first dam structure in the second mold structure; a second dam structure in the third mold structure; and an etching stop film on the substrate, wherein the etching stop film is in contact with the substrate, wherein a lower surface of the first dam structure is on an upper surface of the etching stop film, and a lower surface of the second dam structure is spaced apart from a lower surface of the etching stop film.

### CROSS-REFERENCE TO RELATED APPLICATIONS

This application claims priority from Korean Patent Application No. 10-2024-0161806 filed on Nov. 14, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates semiconductor memory devices and electronic systems including the same, and more particularly, to semiconductor memory devices including memory cells that are three-dimensionally arranged and electronic systems including the same.

In order to satisfy the excellent performance and low price of semiconductor memory devices demanded by consumers, it may be needed to increase the degree of integration of the semiconductor memory devices. Since the degree of integration of the semiconductor memory devices is one of the major factors in determining the price of a product, an increased degree of integration may be needed for the semiconductor memory devices.

Since the degree of integration of two-dimensional or planar semiconductor memory devices is mainly determined by an area occupied by unit memory cells, it may be affected by a level of technology for forming a fine pattern. However, since ultra-expensive equipment may be needed to form the fine pattern, the degree of integration of the two-dimensional semiconductor memory devices is increasing, but may still be limited. Accordingly, three-dimensional semiconductor devices including memory cells that are three-dimensionally arranged are proposed.

### SUMMARY OF THE INVENTION

Aspects of the present disclosure may provide semiconductor memory devices capable of having improved performance and reliability.

Aspects of the present disclosure may also provide electronic systems including a semiconductor memory device capable of having improved performance and reliability.

A semiconductor memory device according to some embodiments of the present disclosure for achieving the above technical object includes a first substrate that includes a first region, a second region, and a third region, wherein the second region is adjacent the first region and the third region; a first mold structure that includes insulating layers and gate electrode layers that are alternately stacked on a first surface of the first substrate in the first region; a second mold structure on the first surface of the first substrate in the second region; a third mold structure on the first surface of the first substrate in the third region; a channel structure that extends into the first mold structure in a first direction that is perpendicular to the first surface of the first substrate; a first dam structure that extends into the second mold structure in the first direction; a second dam structure that extends into the third mold structure in the first direction; and an etching stop film on a second surface of the first substrate that is opposite to the first surface of the first substrate in the first direction, wherein the etching stop film includes a third surface that is in contact with the second surface of the first substrate and a fourth surface that is opposite to the third surface in the first direction, and wherein a lower surface of the first dam structure is on the third surface of the etching stop film, and a lower surface of the second dam structure is spaced apart from the fourth surface of the etching stop film in the first direction.

A semiconductor memory device according to some embodiments of the present disclosure for achieving the above technical object includes a first substrate that includes a first region, a second region, and a third region, wherein the second region is adjacent the first region and the third region; a first mold structure that includes insulating layers and gate electrode layers that are alternately stacked on a first surface of the first substrate in the first region; a second mold structure on the first surface of the first substrate in the second region; a third mold structure on the first surface of the first substrate in the third region; a channel structure that extends into the first mold structure in a vertical direction that is perpendicular to the first surface of the first substrate; a first dam structure that is spaced apart from the channel structure in a horizontal direction that is parallel with the first surface of the first substrate, wherein the first dam structure extends into the second mold structure in the vertical direction, in the second region; a second dam structure that is spaced apart from the first dam structure in the horizontal direction, wherein the second dam structure extends into the third mold structure in the vertical direction, in the third region; and a second substrate on a second surface of the first substrate that is opposite to the first surface of the first substrate in the vertical direction, wherein the second substrate includes peripheral circuit elements, a peripheral wiring structure on the peripheral circuit elements, and a peripheral element isolation film that is adjacent at least one of the peripheral circuit elements and/or the peripheral wiring structure, wherein the peripheral wiring structure includes a first peripheral wiring that is electrically connected to at least one of the peripheral circuit elements and a second peripheral wiring that is connected to the peripheral element isolation film, and wherein at least one of the first dam structure and the second dam structure is electrically connected to the second peripheral wiring.

An electronic system according to some embodiments of the present disclosure for achieving the above technical object includes a main board; a semiconductor memory device that includes a first structure and a second structure that is below the first structure on the main board; and a controller that is electrically connected to the semiconductor memory device on the main board, wherein the first structure includes: a first substrate that includes a first region, a second region, and a third region, wherein the second region and the third region extend around the first region; a first mold structure that includes insulating layers and gate electrode layers alternately stacked on a first surface of the first substrate in the first region; a second mold structure that includes an oxide layer on the first surface of the first substrate in the second region; a third mold structure that includes oxide layers and nitride layers that are alternately stacked on the first surface of the first substrate in the third region; a channel structure that extends into the first mold structure in a first direction that is perpendicular to the first surface of the first substrate; a source structure that is electrically connected to a lower portion of the channel structure on the first surface of the first substrate; a first dam structure that extends into the second mold structure in the first direction; a second dam structure that at least partially extends into the third mold structure in the first direction; an interlayer insulating film on the first mold structure, the second mold structure, and the third mold structure; a bit line contact that extends into the interlayer insulating film and is electrically connected to an upper portion of the channel structure; and an etching stop film that includes a nitride on a second surface of the first substrate that is opposite to the first surface of the first substrate in the first direction, wherein the second structure includes: a second substrate that faces the second surface of the first substrate; peripheral circuit elements on the second substrate; a first peripheral wiring that is electrically connected to at least one of the peripheral circuit elements; and a second peripheral wiring that is connected to an element isolation film that is adjacent at least one of the peripheral circuit elements and/or the first peripheral wiring, wherein the first dam structure is free of having overlap with the etching stop film in a second direction that is parallel with the first surface of the first substrate, wherein the second dam structure extends into the etching stop film, wherein the first dam structure is spaced apart from the first peripheral wiring, and wherein the second dam structure is in contact with the second peripheral wiring.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail example embodiments thereof with reference to the attached drawings, in which:

FIG. 1 is an example block diagram for describing a semiconductor memory device according to some example embodiments;

FIG. 2 is an example circuit diagram for describing a semiconductor memory device according to some example embodiments;

FIG. 3 is a plan view illustrating a configuration before the semiconductor memory device according to some example embodiments is cut into chips;

FIG. 4 is an enlarged view of area P of FIG. 3;

FIG. 5 is cross-sectional views for describing the memory region of FIG. 4, including cross-sectional views taken along lines A-A′ and B-B′ of FIG. 4;

FIG. 6 is an enlarged view for describing area Q1 of FIG. 5;

FIG. 7 is an enlarged view for describing area Q2 of FIG. 5;

FIG. 8 is cross-sectional views illustrating a semiconductor memory device according to some example embodiments;

FIGS. 9 and 10 are views for describing a semiconductor device according to some example embodiments;

FIGS. 11 to 15 are intermediate step views for describing a method for manufacturing a semiconductor memory device according to some example embodiments;

FIGS. 16 to 20 are intermediate step views for describing a method for manufacturing a semiconductor memory device according to some example embodiments;

FIG. 21 is an example block diagram for describing an electronic system according to some example embodiments;

FIG. 22 is an example perspective view for describing an electronic system according to some example embodiments; and

FIG. 23 is a schematic cross-sectional view taken along line I-I of FIG. 22.

### DETAILED DESCRIPTION

It will be understood that, although the terms first, second, etc. may be used herein to describe various elements or components, these elements or components should not be limited by these terms. These terms are only used to distinguish one element or component from another element or component. Therefore, a first element or component mentioned below could be termed a second element or component without departing from the teachings of the present inventive concept.

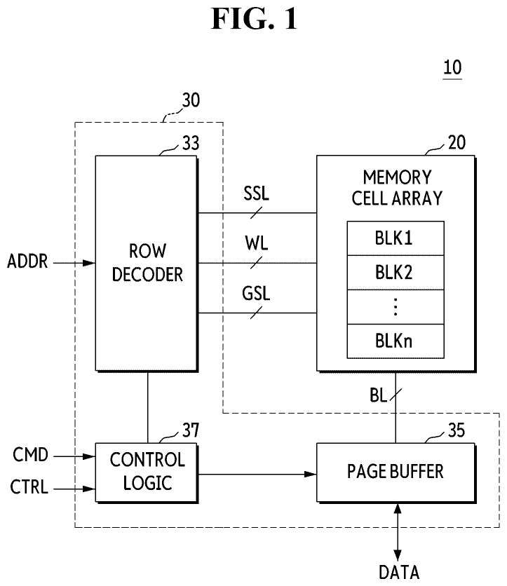

Hereinafter, a semiconductor memory device according to example embodiments will be described with reference to FIGS. 1 to 8.

FIG. 1 is an example block diagram for describing a semiconductor memory device according to some example embodiments.

Referring to FIG. 1, a semiconductor memory device 10 according to some example embodiments may include a memory cell array 20 and a peripheral circuit 30.

The memory cell array 20 may include a plurality of memory cell blocks BLK1 to BLKn. Herein, “n” may be a natural number that is greater than 2. Each of the memory cell blocks BLK1 to BLKn may include a plurality of memory cells. The memory cell array 20 may be (electrically) connected to the peripheral circuit 30 through a bit line BL, a word line WL, at least one string select line SSL, and/or at least one ground select line GSL. Specifically, the memory cell blocks BLK1 to BLKn may be (electrically) connected to a row decoder 33 through the word line WL, the string select line SSL, and the ground select line GSL. In some embodiments, the memory cell blocks BLK1 to BLKn may be (electrically) connected to a page buffer 35 through the bit line BL.

The peripheral circuit 30 may receive an address ADDR, a command CMD, and/or a control signal CTRL from the outside of the semiconductor memory device 10, and may transmit and receive data DATA to and from an external device of the semiconductor memory device 10. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device. The peripheral circuit 30 may include a control logic 37, a row decoder 33, and a page buffer 35. Although not illustrated, the peripheral circuit 30 may further include various sub-circuits such as an input/output circuit, a voltage generating circuit for generating various voltages necessary for an operation of the semiconductor memory device 10, and an error correction circuit for correcting an error in data DATA read from the memory cell array 20.

The control logic 37 may be (electrically) connected to the row decoder 33, the input/output circuit, and the voltage generating circuit. The control logic 37 may control an overall operation of the semiconductor memory device 10. The control logic 37 may generate a variety of internal control signals used in the semiconductor memory device 10 in response to the control signal CTRL. For example, the control logic 37 may adjust a voltage level provided to the word line WL and the bit line BL when performing a memory operation such as a program operation or an erase operation.

The row decoder 33 may select at least one of the plurality of memory cell blocks BLK1 to BLKn in response to the address ADDR, and may select at least one word line WL, at least one string select line SSL, and at least one ground select line GSL of the selected memory cell blocks BLK1 to BLKn. In addition, the row decoder 33 may transfer a voltage for performing a memory operation to the word line WL of the selected memory cell blocks BLK1 to BLKn.

The page buffer 35 may be (electrically) connected to the memory cell array 20 through the bit line BL. The page buffer 35 may operate as a writer driver or a sense amplifier. Specifically, when performing the program operation, the page buffer 35 may operate as the write driver to apply a voltage according to the data DATA to be stored in the memory cell array 20 to the bit line BL. Meanwhile, when performing the read operation, the page buffer 35 may operate as the sense amplifier to sense the data DATA stored in the memory cell array 20.

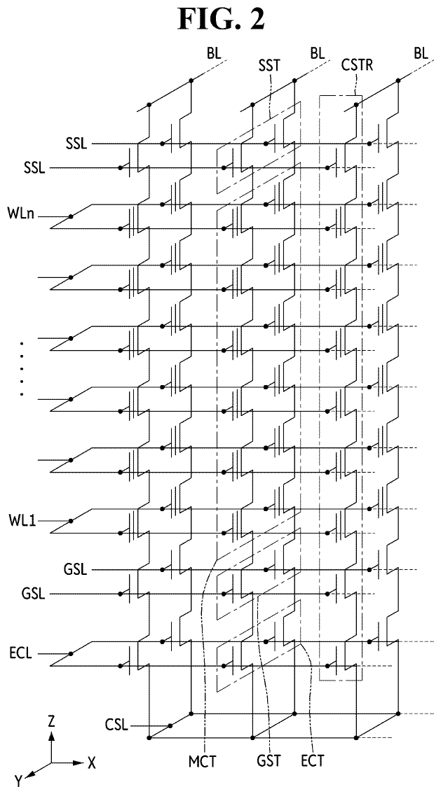

FIG. 2 is an example circuit diagram for describing a semiconductor memory device according to some example embodiments.

Referring to FIG. 2, the memory cell array (e.g., the memory cell array 20 in FIG. 1) of the semiconductor memory device according to some example embodiments may include a common source line CSL, a plurality of bit lines BL, and a plurality of cell strings CSTR.

The common source line CSL may extend in a first direction X. In some example embodiments, a plurality of common source lines CSL may be two-dimensionally arranged. For example, the plurality of common source lines CSL may be spaced apart from each other and each extend in the first direction X. The common source lines CSL may be applied with the same electrical voltage, or may be applied with different voltages to be separately controlled.

The plurality of bit lines BL may be two-dimensionally arranged. For example, the bit lines BL may be spaced apart from each other and each extend in a second direction Y intersecting (crossing) the first direction X. The plurality of cell strings CSTR may be (electrically) connected in parallel to each of the bit lines BL. The cell strings CSTR may be commonly (and electrically) connected to the common source line CSL. That is, the plurality of cell strings CSTR may be disposed between the bit lines BL and the common source line CSL.

Each of the cell strings CSTR may include a ground select transistor GST (electrically) connected to the common source line CSL, a string select transistor SST (electrically) connected to the bit line BL, and a plurality of memory cell transistors MCT disposed between the ground select transistor GST and the string select transistor SST. Each of the memory cell transistors MCT may include a data storage element. The ground select transistor GST, the string select transistor SST, and the memory cell transistors MCT may be (electrically) connected in series.

The common source line CSL may be commonly (and electrically) connected to sources of the ground select transistors GST. In addition, the ground select line GSL, a plurality of word lines WL1 to WLn, and the string select line SSL may be disposed between the common source line CSL and the bit line BL. Herein, “n” may be a natural number that is greater than 1. The ground select line GSL may be used as a gate electrode of the ground select transistor GST, the word lines WL1 to WLn may be used as gate electrodes of the memory cell transistors MCT, and the string select line SSL may be used as a gate electrode of the string select transistor SST.

In some example embodiments, an erase control transistor ECT may be disposed between the common source line CSL and the ground select transistor GST. The common source line CSL may be commonly (and electrically) connected to sources of the erase control transistors ECT. In addition, an erase control line ECL may be disposed between the common source line CSL and the ground select line GSL. The erase control line ECL may be used as a gate electrode of the erase control transistor ECT. The erase control transistors ECT may generate a gate induced drain leakage (GIDL) to perform an erase operation of the memory cell array.

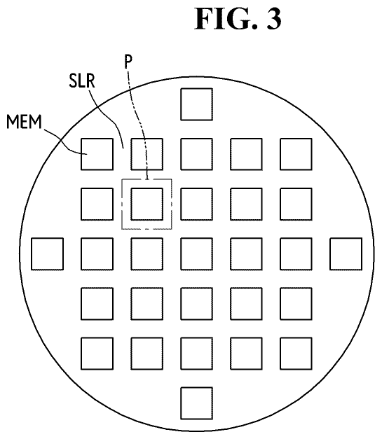

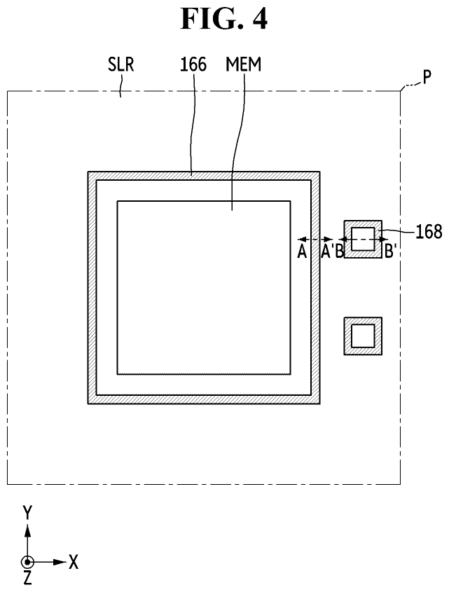

FIG. 3 is a plan view illustrating a configuration before the semiconductor memory device according to some example embodiments is cut into chips. FIG. 4 is an enlarged view of area P of FIG. 3.

Referring to FIGS. 3 and 4, the semiconductor memory device according to some example embodiments may include one or more memory regions MEM and a scribe lane region SLR extending around (e.g., surrounding) the memory region MEM (in a plan view), before being cut into the chips. The memory regions MEM may be arranged in a grid pattern with the scribe lane region SLR interposed therebetween. The scribe lane region SLR may be a region outside the memory region MEM. When the semiconductor memory device is cut into the chips, the scribe lane region SLR may be partially and/or completely lost by dicing.

Although not specifically illustrated, the memory region MEM may include a peripheral region (not illustrated) that includes a row decoder and a sense amplifier.

In some example embodiments, the plurality of memory cells may be three-dimensionally arranged in the memory region MEM. That is, the semiconductor memory device according to some example embodiments may be a three-dimensional memory device. The word line of the semiconductor memory device may be (electrically) connected to each of the plurality of memory cells in a stacked structure. In addition, the word line may be drawn out in a stepwise manner and (electrically) connected to the row decoder, etc.

The row decoder and the sense amplifier may contribute to the operation of the memory cell. The row decoder may specify a memory cell to be operated. The sense amplifier may sense data stored in the memory cell.

In some example embodiments, a first dam structure 166 and a second dam structure 168 may be disposed in (within) the scribe lane region SLR (in a plan view). The first dam structure 166 and the second dam structure 168 may be disposed at a periphery (e.g., outside in a plan view) of the memory region MEM. In a plan view, the first dam structure 166 may extend around (e.g., surround) the memory region MEM. In a plan view, the second dam structure 168 may have at least one closed-circuit structure.

It is illustrated in FIG. 4 that the first dam structure 166 is disposed only at the periphery (e.g., outside in a plan view) of the memory region MEM as a single closed-circuit structure, but the number and position of the first dam structure 166 are not limited to those illustrated. In addition, it is illustrated that the second dam structure 168 is disposed only at the periphery (e.g., outside in a plan view) of the memory region MEM as a single closed-circuit structure, but the number and position of the second dam structure 168 are not limited to those illustrated.

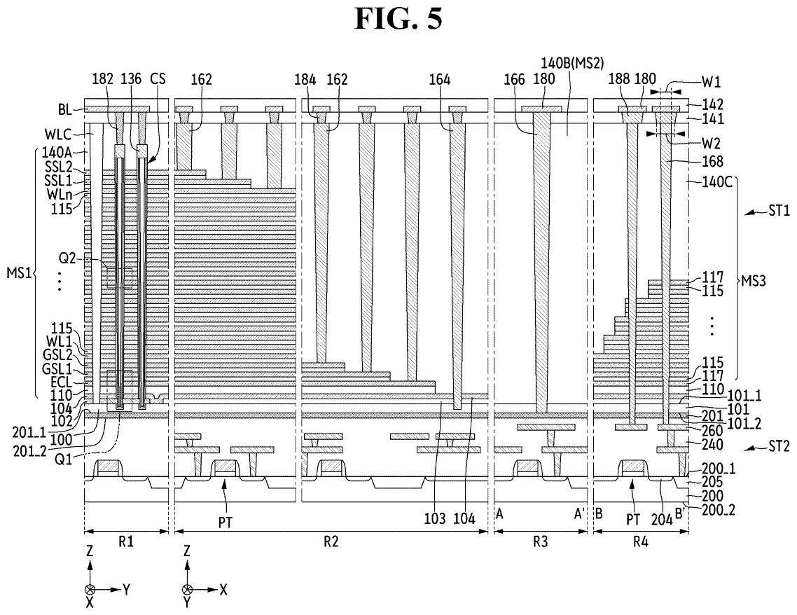

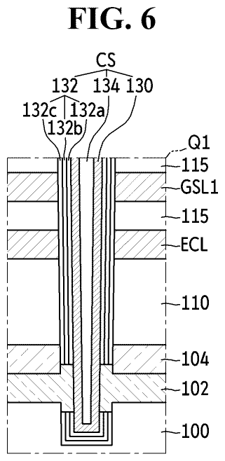

FIG. 5 is cross-sectional views for describing the memory region of FIG. 4, including cross-sectional views taken along lines A-A′ and B-B′ of FIG. 4. FIG. 6 is an enlarged view for describing area Q1 of FIG. 5.

Referring to FIGS. 5 and 6, the semiconductor memory device according to some example embodiments may include a first structure ST1 and a second structure ST2 below the first structure ST1.

For reference, first and second regions R1 and R2 of FIG. 5 described below may be included in the memory region MEM of FIG. 4. Third and fourth regions R3 and R4 of FIG. 5 may be included in the scribe lane region SLR of FIG. 4.

The first structure ST1 may include a cell substrate 100, first, second, and third mold structures MS1, MS2, and MS3, a channel structure CS, a first dam structure 166, a second dam structure 168, an etching stop film 201, first and second interlayer insulating films 141 and 142, first and second wiring lines 184 and 188, a word line cutting region WLC, a bit line BL, a cell contact 162, a source contact 164, and a third wiring line 180.

The cell substrate 100 may include, for example, a semiconductor substrate such as a silicon substrate, a germanium substrate, and/or a silicon-germanium substrate. In some embodiments, the cell substrate 100 may include a silicon-on-insulator (SOI) substrate or a germanium-on-insulator (GOI) substrate. In some example embodiments, the cell substrate 100 may include impurities. For example, the cell substrate 100 may include n-type impurities (e.g., phosphorus (P), arsenic (As), etc.).

The cell substrate 100 may include a first region R1 and a second region R2. The memory cell array (e.g., the memory cell array 20 in FIG. 1) including the plurality of memory cells may be formed in the first region R1. For example, a channel structure CS, a bit line BL, and gate electrodes ECL, GSL1, GSL2, WL1 to WLn, SSL1, and SSL2, which will be described later, may be disposed in the first region R1. Herein, “n” may be a natural number that is greater than 1. In the following description, a surface of the cell substrate 100 on which the memory cell array is disposed may be referred to as a front side of the cell substrate 100 (e.g., an upper surface of the cell substrate 100 in FIG. 5). A surface of the cell substrate 100 opposite to the front side of the cell substrate 100 (in a third direction Z) may be referred to as a back side of the cell substrate 100 (e.g., a lower surface of the cell substrate 100 in FIG. 5). The third direction Z may be referred to as a vertical direction. The third direction Z may be perpendicular to the upper surface of the cell substrate 100 (and/or the upper surface of the insulating substrate 101).

The second region R2 may extend from (may be adjacent) the first region R1. The second region R2 may be disposed around (may extend around) the first region R1. Gate electrodes ECL, GSL1, GSL2, WL1 to WLn, SSL1, and SSL2, which will be described later, may be stacked in a step shape in the second region R2.

An insulating substrate 101 may include a third region R3 and a fourth region R4 around the first region R1. The third region R3 may be adjacent the second region R2. For example, the third region R3 may be between the second region R2 and the fourth region R4 in the first direction X. The third region R3 may extend around the second region R2, and the fourth region R4 may extend around the third region R3. The insulating substrate 101 (the third region R3 of the insulating substrate 101) may be adjacent the cell substrate 100 (the second region R2 of the cell substrate 100).

The third region R3 may be disposed outside the first region R1 and the second region R2. A first dam structure 166 described later may be disposed in the third region R3. The fourth region R4 may be disposed around the third region R3. The fourth region R4 may be disposed outside the third region R3. A second dam structure 168 described later may be disposed in the fourth region R4.

The insulating substrate 101 may include, but is not limited to, for example, silicon oxide, silicon nitride, silicon oxynitride, and/or silicon carbide.

The insulating substrate 101 may include a first surface 101_1 and a second surface 101_2 that are opposite to each other (in the third direction Z). The first surface 101_1 may refer to an upper surface of the insulating substrate 101 (in FIG. 5), and the second surface 101_2 may refer to a lower surface of the insulating substrate 101 (in FIG. 5). The upper surface of the insulating substrate 101 may be coplanar with the front side of the cell substrate 100, but is not limited thereto. The lower surface of the insulating substrate 101 may be coplanar with the back side of the cell substrate 100, but is not limited thereto.

The first mold structure MS1 may be formed on the front side of the cell substrate 100. The first mold structure MS1 may include a plurality of gate electrodes ECL, GSL1, GSL2, WL1 to WLn, SSL1, and SSL2, a plurality of mold insulating films 110 and 115, and a first insulating film 140A stacked on the cell substrate 100. Each of the gate electrodes ECL, GSL1, GSL2, WL1 to WLn, SSL1, and SSL2 and each of the mold insulating films 110 and 115 may have a layered structure extending parallel to the front side of the cell substrate 100 (e.g., extending in the first direction X and/or the second direction Y). The gate electrodes ECL, GSL1, GSL2, WL1 to WLn, SSL1, and SSL2 may be sequentially stacked on the cell substrate 100 while being spaced apart from each other by the mold insulating films 110 and/or 115.

In some example embodiments, the gate electrodes ECL, GSL1, GSL2, WL1 to WLn, SSL1, and SSL2 may include an erase control line ECL, ground select lines GSL1 and GSL2, and a plurality of word lines WL1 to WLn sequentially stacked on the cell substrate 100. The ground select lines GSL1 and GSL2 may include a first ground select line GSL1 and a second ground select line GSL2 that are sequentially stacked. Although it is illustrated that the gate electrodes ECL, GSL1, GSL2, WL1 to WLn, SSL1, and SSL2 include only two ground select lines GSL1 and GSL2, this is only an example, and the gate electrodes ECL, GSL1, GSL2, WL1 to WLn, SSL1, and SSL2 may also include three or more ground select lines. In some example embodiments, the erase control line ECL may be omitted.

In some example embodiments, the gate electrodes ECL, GSL1, GSL2, WL1 to WLn, SSL1, and SSL2 may include string select lines SSL1 and SSL2 that are sequentially stacked on the plurality of word lines WL1 to WLn. The string select lines SSL1 and SSL2 may include a first string select line SSL1 and a second string select line SSL2 that are sequentially stacked. Although it is illustrated that the gate electrodes ECL, GSL1, GSL2, WL1 to WLn, SSL1, and SSL2 include only two string select lines SSL1 and SSL2, this is only an example, and the gate electrodes ECL, GSL1, GSL2, WL1 to WLn, SSL1, and SSL2 may also include three or more string select lines.

Each of the gate electrodes ECL, GSL1, GSL2, WL1 to WLn, SSL1, and SSL2 may include a conductive material, for example, a metal such as tungsten (W), cobalt (Co), and/or nickel (Ni), and/or a semiconductor material such as silicon, but is not limited thereto.

The mold insulating films 110 and 115 may each include an insulating material, for example, silicon oxide, silicon nitride, and/or silicon oxynitride, but are not limited thereto.

The first insulating film 140A may be formed on the cell substrate 100 to be on (e.g., to cover or overlap) the gate electrodes ECL, GSL1, GSL2, WL1 to WLn, SSL1, and SSL2 and the mold insulating films 110 and 115. The first insulating film 140A may include, for example, silicon oxide, silicon oxynitride, and/or a low-k material having a dielectric constant lower than that of silicon oxide, but is not limited thereto.

In some example embodiments, the second mold structure MS2 of the third region R3 may include a second insulating film 140B on the insulating substrate 101. The second insulating film 140B may include, for example, silicon oxide, silicon oxynitride, and/or a low-k material having a dielectric constant lower than that of silicon oxide, but is not limited thereto. Although not specifically illustrated, when the second insulating film 140B and the insulating substrate 101 include the same material, an interface may not exist between the second insulating film 140B and the insulating substrate 101.

In some example embodiments, the third mold structure MS3 of the fourth region R4 may include a plurality of mold sacrificial films 117, a plurality of mold insulating films 110 and 115, and a third insulating film 140C that are alternately stacked on the insulating substrate 101. Each of the mold sacrificial films 117 and each of the mold insulating films 110 and 115 may have a layered structure extending parallel to the upper surface of the insulating substrate 101. The mold sacrificial films 117 may be sequentially stacked on the insulating substrate 101 while being spaced apart from each other by the mold insulating films 110 and 115. For example, each of the mold sacrificial films 117 and each of the mold insulating films 110 and 115 may be stacked in a step shape, but are not limited thereto.

The mold sacrificial films 117 may each include an insulating material, for example, silicon oxide, silicon nitride, and/or silicon oxynitride, but is not limited thereto. In some example embodiments, the mold sacrificial films 117 may include a material having an etch selectivity with respect to the mold insulating films 110 and 115. As an example, the mold insulating films 110 and 115 may include silicon oxide, and the mold sacrificial films 117 may include silicon nitride.

The third insulating film 140C may be formed on the insulating substrate 101 to be on (e.g., to cover or overlap) the mold sacrificial films 117 and the mold insulating films 110 and 115. The third insulating film 140C may include, for example, silicon oxide, silicon oxynitride, and/or a low-k material having a dielectric constant lower than that of silicon oxide, but is not limited thereto

The second mold structure MS2 and the third mold structure MS3 may include different materials. For example, the second mold structure MS2 may include silicon oxide, and the third mold structure MS3 may include silicon nitride. In some embodiments, the second mold structure MS2 and the third mold structure MS3 may include materials having different etching rates.

The channel structure CS may be formed within the first mold structure MS1 of the first region R1. The channel structure CS may extend in the third direction Z to extend into (e.g., penetrate through) the first mold structure MS1. For example, the channel structure CS may have a pillar shape (e.g., a cylindrical shape) extending in the third direction Z. Accordingly, the channel structure CS may intersect each of the gate electrodes ECL, GSL1, GSL2, WL1 to WLn, SSL1, and SSL2.

As illustrated in FIG. 6, the channel structure CS may include a semiconductor pattern 130 and an information storage film 132.

The semiconductor pattern 130 may extend in the third direction Z to extend into (e.g., penetrate through) the first mold structure MS1. It is only illustrated that the semiconductor pattern 130 has a cup shape, but this is only an example. For example, the semiconductor pattern 130 may also have various shapes, such as a cylindrical shape, a square barrel shape, and a closely packed pillar shape. The semiconductor pattern 130 may include, but is not limited to, for example, a semiconductor material such as single crystal silicon, polycrystalline silicon, an organic semiconductor material, and/or a carbon nanostructure.

The information storage film 132 may be interposed between the semiconductor pattern 130 and each of the gate electrodes ECL, GSL1, GSL2 WL1 to WLn, SSL1, and SSL2. For example, the information storage film 132 may extend along an outer side surface of the semiconductor pattern 130. The information storage film 132 may include, for example, silicon oxide, silicon nitride, silicon oxynitride, and/or a high-k material having a dielectric constant higher than that of silicon oxide. The high-k material may include, for example, aluminum oxide, hafnium oxide, lanthanum oxide, tantalum oxide, titanium oxide, lanthanum hafnium oxide, lanthanum aluminum oxide, dysprosium scandium oxide, and/or a combination thereof.

In some example embodiments, the information storage film 132 may be formed as a multi-film. For example, as illustrated in FIG. 6, the information storage film 132 may include a tunnel insulating film 132a, a charge storage film 132b, and a blocking insulating film 132c sequentially stacked on the outer side surface of the semiconductor pattern 130.

The tunnel insulating film 132a may include, for example, silicon oxide and/or a high-k material (e.g., aluminum oxide (Al₂O₃) and/or hafnium oxide (HfO₂)) having a dielectric constant higher than that of silicon oxide. The charge storage film 132b may include, for example, silicon nitride. The blocking insulating film 132c may include, for example, silicon oxide and/or a high-k material (e.g., aluminum oxide (Al₂O₃) and/or hafnium oxide (HfO₂)) having a dielectric constant higher than that of silicon oxide.

In some example embodiments, the channel structure CS may further include a filling pattern 134. The filling pattern 134 may be formed to (at least partially) fill an inner portion of the semiconductor pattern 130 having the cup shape. The filling pattern 134 may include an insulating material, for example, silicon oxide, but is not limited thereto.

In some example embodiments, the channel structure CS may further include a channel pad 136. The channel pad 136 may be formed to be (electrically) connected to an upper portion of the semiconductor pattern 130. The channel pad 136 may include, for example, polysilicon doped with impurities, but is not limited thereto.

In some example embodiments, the plurality of channel structures CS may be arranged in a zigzag shape (in a plan view). Although not specifically illustrated, in a plan view, the plurality of channel structures CS may be arranged alternately in the first direction X and the second direction Y parallel to the front side of the cell substrate 100. The plurality of channel structures CS arranged in the zigzag shape may further improve a degree of integration of semiconductor memory devices. In some example embodiments, the plurality of channel structures CS may be arranged in a honeycomb shape (in a plan view).

In some example embodiments, source structures 102 and 104 may be formed on the cell substrate 100. The source structures 102 and 104 may be interposed between the cell substrate 100 and the first mold structure MS1. For example, the source structures 102 and 104 may extend along the upper surface of the cell substrate 100. The source structures 102 and 104 may be formed to be (electrically) connected to the semiconductor pattern 130 of the channel structure CS. For example, as illustrated in FIG. 6, the source structures 102 and 104 may extend into (e.g., penetrate through) the information storage film 132 and be in contact with the semiconductor pattern 130. The source structures 102 and 104 may be provided as the common source lines (e.g., CSL in FIG. 2) of the semiconductor memory device. The source structures 102 and 104 may include, for example, polysilicon and/or metal doped with impurities, but are not limited thereto.

In some example embodiments, the channel structure CS may extend into (e.g., penetrate through) the source structures 102 and 104. For example, a lower portion of the channel structure CS may penetrate through the source structures 102 and 104 and be disposed within the cell substrate 100.

In some example embodiments, the source structures 102 and 104 may be formed as a multi-layer. For example, the source structures 102 and 104 may include a first source layer 102 and a second source layer 104 that are sequentially stacked on the cell substrate 100. The first source layer 102 and the second source layer 104 may each include polysilicon doped with impurities and/or polysilicon not doped with impurities, but are not limited thereto. The first source layer 102 may be in contact with the semiconductor pattern 130 and provided as the common source line (e.g., CSL in FIG. 2) of the semiconductor memory device. The second source layer 104 may be used as a support layer for preventing collapsing or falling-down of the mold stack in a replacement process for forming the first source layer 102. In some embodiments, the second source layer 104 may be spaced apart from the semiconductor pattern 130.

Although not illustrated, a base insulating film may also be interposed between the cell substrate 100 and the source structures 102 and 104. The base insulating film may include, for example, silicon oxide, silicon nitride, and/or silicon oxynitride, but is not limited thereto.

In some example embodiments, a source sacrificial film 103 may be formed on a portion of the cell substrate 100. For example, the source sacrificial film 103 may be formed on the second region R2 of the cell substrate 100. The source sacrificial film 103 may include a material having an etch selectivity with respect to the mold insulating films 110 and 115. As an example, the mold insulating films 110 and 115 may include silicon oxide, and the source sacrificial film 103 may include silicon nitride. The source sacrificial film 103 may be a layer that remains after a portion thereof is replaced with the first source layer 102 during a manufacturing process of the source structures 102 and 104.

The word line cutting region WLC may extend into the first mold structure MS1 in the third direction Z. Although not specifically illustrated, the word line cutting region WLC may extend in the first direction X in a plan view. The word line cutting region WLC may penetrate through the first mold structure MS1 in the third direction Z. The first mold structure MS1 may be divided by the word line cutting regions WLC to form a plurality of memory cell blocks (e.g., BLK1 to BLKn in FIG. 1). Two memory cell blocks (e.g., a first cell block BLK1 and a second cell block BLK2) may be defined by separating the first mold structure MS1 between the word line cutting regions WLC.

The bit line BL may be formed on the first mold structure MS1. Although not specifically illustrated, in plan view, the bit line BL may extend in the second direction Y to intersect the word line cutting region WLC. In addition, the bit line BL may extend in the second direction Y and be (electrically) connected to the plurality of channel structures CS arranged along the second direction Y. For example, a bit line contact 182 (electrically) connected to an upper portion of each of the channel structures CS may be formed in the first interlayer insulating film 141. The bit line contact 182 may extend into (e.g., penetrate through) the first interlayer insulating film 141. The bit line BL may be electrically connected to the channel structures CS through the bit line contact 182.

The cell contact 162 may be disposed in the second region R2. The cell contact 162 may be (electrically) connected to each of the gate electrodes ECL, GSL1, GSL2, WL1 to WLn, SSL1, and SSL2. For example, the cell contact 162 may extend in the third direction Z in (within) the first insulating film 140A and be (electrically) connected to each of the gate electrodes ECL, GSL1, GSL2, WL1 to WLn, SSL1, and SSL2.

The source contact 164 may be disposed in the second region R2. The source contact 164 may be connected to the source structure 104. For example, the source contact 164 may extend in the third direction Z in the first insulating film 140A and be (electrically) connected to the cell substrate 100. The source contact 164 may extend into (e.g., penetrate through) the first insulating film 140A to be (electrically) connected to the cell substate 100.

The first dam structure 166 may be disposed in the third region R3. For example, the first dam structure 166 may extend in the third direction Z in the second mold structure MS2 of the third region R3. The first dam structure 166 may completely penetrate through the second mold structure MS2 in the third direction Z.

The second dam structure 168 may be disposed in the fourth region R4. For example, the second dam structure 168 may extend in the third direction Z in the third mold structure MS3 of the fourth region R4. The second dam structure 168 may completely penetrate through the third mold structure MS3 in the third direction Z.

The first and second dam structures 166 and 168 may include a conductive material. For example, the first and second dam structures 166 and 168 may each include tungsten, titanium, tantalum, copper, aluminum, titanium nitride, tantalum nitride, tungsten nitride, and/or a combination thereof, but are not limited thereto.

The first interlayer insulating film 141 may be disposed on the first, second, and third mold structures MS1, MS2, and MS3. A fourth wiring line (not illustrated), which is a partial region of the first dam structure 166, may be disposed in the first interlayer insulating film 141 on the third region R3. The second wiring line 188 disposed on the second dam structure 168 and (electrically) connected to the second dam structure 168 may be disposed in the first interlayer insulating film 141 on the fourth region R4.

A width of a lower surface of the fourth wiring line (not illustrated) may be the same as a width of an upper surface of the first dam structure 166. A width W2 of the lower surface of the second wiring line 188 may be greater than a width W1 of an upper surface of the second dam structure 168.

The cell contact 162, the source contact 164, the first dam structure 166, and the second dam structure 168 may each be (electrically) connected to the third wiring line 180. For example, a second interlayer insulating film 142 may be formed on the first interlayer insulating film 141. The third wiring line 180 may be formed in (within) the second interlayer insulating film 142. The cell contact 162 and the source contact 164 may each be (electrically) connected to the third wiring line 180 by the first wiring line 184. The first dam structure 166 and the second dam structure 168 may each be (electrically) connected to the third wiring line 180 by the fourth wiring line (not illustrated) and the second wiring line 188 (respectively).

The etching stop film 201 may be disposed on the back side (the lower surface) of the cell substrate 100 and the lower surface of the insulating substrate 101. The etching stop film 201 may include a first surface 201_1 in contact with the back side of the cell substrate 100 and the lower surface of the insulating substrate 101 and a second surface 201_2 opposite to the first surface 201_1 (in the third direction Z). The first surface 201_1 may refer to an upper surface of the etching stop film 201, and the second surface 201_2 may refer to a lower surface of the etching stop film 201. For example, the etching stop film 201 may include, but is not limited to, a nitride.

In the third direction Z, a lower surface of the first dam structure 166 may be disposed on the upper surface of the etching stop film 201, and a lower surface of the second dam structure 168 may be disposed at a lower level than the lower surface of the etching stop film 201. Herein, the term “level”, “vertical level”, “height”, or the like may refer to a relative location with respect to a reference element in the third direction Z in the drawings. For example, the lower surface of the etching stop film 201 may be in contact with the second structure ST2, and the second dam structure 168 may extend into the second structure ST2 as the lower surface of the second dam structure 168 is described as lower than the lower surface of the etching stop film 201.

In the third direction Z, the first dam structure 166 may not penetrate through (e.g., may not extend into) the etching stop film 201. The second dam structure 168 may partially extend into a second structure ST2 described later by penetrating through the etching stop film 201. The first dam structure 166 may not be disposed within the etching stop film 201, and the second dam structure 168 may extend at least partially into the etching stop film 201.

The second structure ST2 may include a peripheral circuit board 200, a peripheral circuit element PT, and a peripheral wiring structure 260.

The peripheral circuit board 200 may be disposed below the cell substrate 100 and the insulating substrate 101. The peripheral circuit board 200 may be disposed on the etching stop film 201. For example, an upper surface of the peripheral circuit board 200 may face the lower surface of the cell substrate 100. The peripheral circuit board 200 may include, for example, a semiconductor substrate such as a silicon substrate, a germanium substrate, or a silicon-germanium substrate. In some embodiments, the peripheral circuit board 200 may include a silicon-on-insulator (SOI) substrate or a germanium-on-insulator (GOI) substrate.

The peripheral circuit element PT may be formed on (in) the peripheral circuit board 200. The peripheral circuit element PT may constitute the peripheral circuit (e.g., the peripheral circuit 30 in FIG. 1) that controls the operation of the semiconductor memory device. For example, the peripheral circuit element PT may include the control logic (e.g., the control logic 37 in FIG. 1), the row decoder (e.g., the row decoder 33 in FIG. 1), and the page buffer (e.g., the page buffer 35 in FIG. 1). In the following description, a surface 200_1 of the peripheral circuit board 200 on which the peripheral circuit element PT is disposed may be referred to as a front side of the peripheral circuit board 200. Conversely, a surface 200_2 of the peripheral circuit board 200 opposite to the front side of the peripheral circuit board 200 (in the third direction Z) may be referred to as a back side of the peripheral circuit board 200.

The peripheral circuit element PT may include, but is not limited to, for example, a transistor. For example, the peripheral circuit element PT may include various active elements such as transistors, as well as various passive elements such as capacitors, resistors, and inductors.

The peripheral circuit elements PT may be isolated by a peripheral element isolation film 205. For example, the peripheral element isolation film 205 may be provided within the peripheral circuit board 200. The peripheral element isolation film 205 may be a shallow trench isolation (STI) film. The peripheral element isolation film 205 may define active regions of the peripheral circuit elements PT. The peripheral element isolation film 205 may include an insulating material. The peripheral element isolation film 205 may include, for example, silicon nitride, silicon oxide, and/or silicon oxynitride.

In some example embodiments, the back side of the cell substrate 100 and the lower surface of the insulating substrate 101 may face the front side of the peripheral circuit board 200. For example, an inter-wiring insulating film 240 on (covering or overlapping) the peripheral circuit element PT may be formed on the front side of the peripheral circuit board 200. The cell substrate 100 and/or the insulating substrate 101 may be stacked on an upper surface of the inter-wiring insulating film 240.

The peripheral wiring structure 260 (electrically) connected to the peripheral circuit element PT may be formed in (within) the inter-wiring insulating film 240. The peripheral wiring structure 260 may include a first peripheral wiring (electrically) connected to the peripheral circuit element PT and a second peripheral wiring connected to the peripheral element isolation film 205. Here, the first peripheral wiring may refer to a peripheral wiring structure 260 (electrically) connected to a source/drain region 204 of the peripheral circuit element PT, and the second peripheral wiring may refer to a peripheral wiring structure 260 connected to the peripheral element isolation film 205. The first peripheral wiring may include a via and a wiring that are (electrically) connected to the source/drain region 204 of the peripheral circuit element PT. The second peripheral wiring may include a via and a wiring that are connected to the peripheral element isolation film 205.

At least one of the first and second dam structures 166 and 168 may be (electrically) connected to the second peripheral wiring described above. That is, at least one of the first and second dam structures 166 and 168 may be (electrically) connected to the second peripheral wiring without being (electrically) connected to the first peripheral wiring. For example, the second dam structure 168 may be (electrically) connected to the second peripheral wiring without being (electrically) connected to the first peripheral wiring.

In the third direction Z, the first dam structure 166 may be disposed to be spaced apart from the peripheral wiring structure 260, and the second dam structure 168 may be (electrically) connected to at least one of the peripheral wiring structures 260. The first dam structure 166 may not be (electrically) connected to the first peripheral wiring. The second dam structure 168 may extend into (e.g., penetrate through) the third mold structure MS3 and the etching stop film 201 and be (electrically) connected to the second peripheral wiring.

The lower surface of the first dam structure 166 may be in contact with the upper surface of the etching stop film 201. The lower surface of the second dam structure 168 may be in contact with the upper surface of the peripheral wiring structure 260.

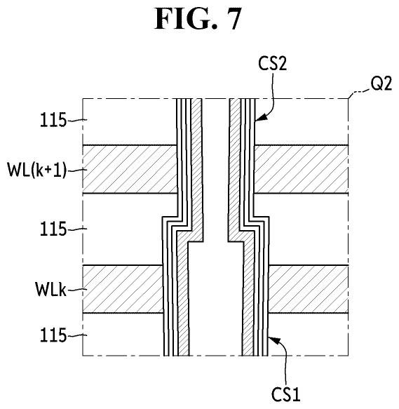

FIG. 7 is an enlarged view for describing area Q2 of FIG. 5. For convenience of explanation, points different from those described with reference to FIGS. 1 to 6 will be mainly described.

Referring to FIG. 7, in some example embodiments, the channel structure CS may include a first channel CS1 and a second channel CS2 that are connected to each other. For example, the channel structure CS may be formed through a process for the first channel CS1 and a process for the second channel CS2. The first channel CS1 may be a lower portion of the channel structure CS, and the second channel CS2 may be an upper portion of the channel structure CS. At a boundary between the first channel CS1 and the second channel CS2, a width of the first channel CS1 may be greater than a width of the second channel CS2. The channel structure CS may have a bending portion at the boundary between the first channel CS1 and the second channel CS2.

In addition, a word line positioned near (adjacent) the boundary between the first channel CS1 and the second channel CS2 may be a dummy word line. For example, a word line WLk (k is a natural number smaller than n) and a word line WL(k+1) forming the boundary between the first channel CS1 and the second channel CS2 may be the dummy word lines. In this case, data may not be stored in memory cells (electrically) connected to the dummy word line. In some embodiments, the number of pages corresponding to the memory cells (electrically) connected to the dummy word line may be smaller than the number of pages corresponding to memory cells (electrically) connected to a normal word line. A voltage level applied to the dummy word line may be different from a voltage level applied to the normal word line.

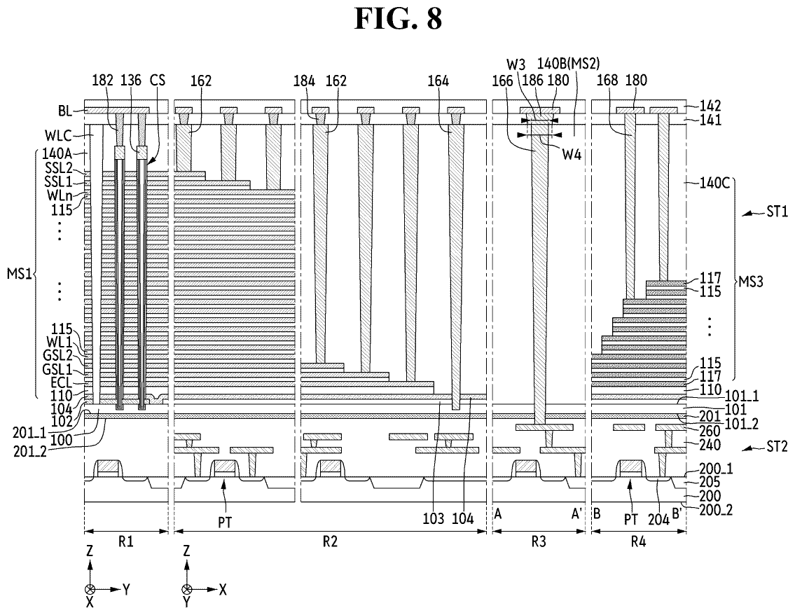

FIG. 8 is cross-sectional views illustrating a semiconductor memory device according to some example embodiments. For convenience of explanation, points different from those described with reference to FIGS. 1 to 7 will be mainly described.

Referring to FIG. 8, the lower surface of the first dam structure 166 may be in contact with the upper surface of the peripheral wiring structure 260. The lower surface of the second dam structure 168 may be in contact with the upper surface of the mold sacrificial film 117.

In the third direction Z, the first dam structure 166 may be (electrically) connected to at least one of the peripheral wiring structures 260, and the second dam structure 168 may be disposed to be spaced apart from the peripheral wiring structure 260. The first dam structure 166 may be (electrically) connected to the peripheral wiring that is connected to the peripheral element isolation film 205.

The first dam structure 166 may extend into (e.g., penetrate through) the second mold structure MS2 and the etching stop film 201 and be (electrically) connected to any one of the peripheral wiring structures 260. The first dam structure 166 may completely penetrate through the second mold structure MS2 in the third direction Z.

The second dam structure 168 may be in contact with the upper surface of the mold sacrificial film 117 of the third mold structure MS3. The second dam structure 168 may only partially penetrate through the third mold structure MS3 in the third direction Z.

A fifth wiring line 186 disposed on the first dam structure 166 and (electrically) connected to the first dam structure 166 may be disposed in (within) the first interlayer insulating film 141 on the third region R3. A sixth wiring line (not illustrated), which is a partial region of the second dam structure 168, may be disposed in (within) the first interlayer insulating film 141 on the fourth region R4.

A width W4 of a lower surface of the fifth wiring line 186 may be greater than a width W3 of the upper surface of the first dam structure 166. A width of a lower surface of the sixth wiring line (not illustrated) may be the same as a width of the upper surface of the second dam structure 168.

The first dam structure 166 and the second dam structure 168 may each be (electrically) connected to the third wiring line 180 by the fifth wiring line 186 and the sixth wiring line (not illustrated) (respectively).

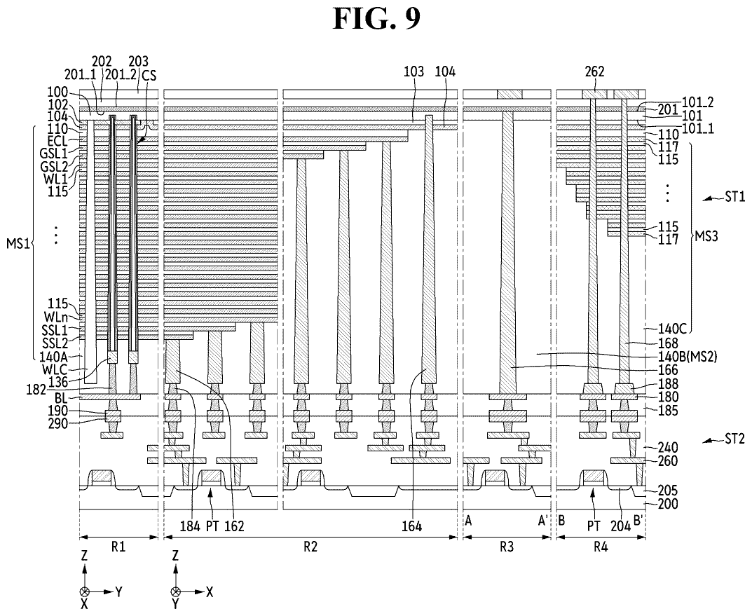

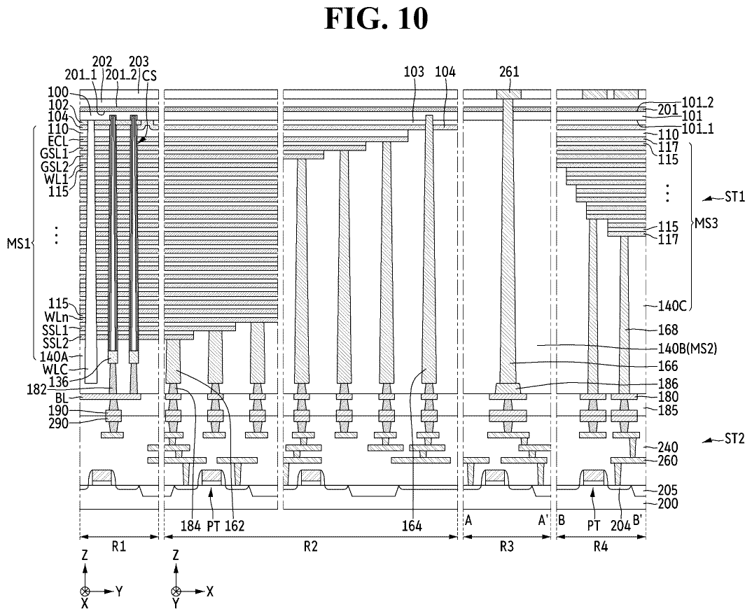

FIGS. 9 and 10 are views for describing a semiconductor device according to some example embodiments. For convenience of explanation, points different from those described with reference to FIGS. 1 to 8 will be mainly described.

Referring to FIG. 9, in the semiconductor memory device according to some example embodiments, the front side of the cell substrate 100 faces the front side of the peripheral circuit board 200.

For example, the semiconductor memory device according to some example embodiments may have a chip to chip (C2C) structure. The C2C structure means fabricating an upper chip including the first structure ST1 on a first wafer (e.g., the cell substrate 100), fabricating a lower chip including the second structure ST2 on a second wafer (e.g., the peripheral circuit board 200) different from the first wafer, and then connecting the upper chip and the lower chip to each other by a bonding method.

As an example, the bonding method may refer to a method of electrically connecting a first bonding metal 190 formed on the uppermost metal layer of the upper chip and a second bonding metal 290 formed on the uppermost metal layer of the lower chip to each other. For example, when the first bonding metal 190 and the second bonding metal 290 are formed of copper (Cu), the bonding method may be a Cu—Cu bonding method. However, this is only an example, and the first bonding metal 190 and the second bonding metal 290 may also be formed of various other metals such as aluminum (Al) and/or tungsten (W).

As the first bonding metal 190 and the second bonding metal 290 within each of the inter-wiring insulating films 185 and 240 are bonded, the third wiring line 180 may be (electrically) connected to the peripheral wiring structure 260. Through this, the bit line BL, each of the gate electrodes ECL, GSL1, GSL2, WL1 to WLn, SSL1, and SSL2, and/or the source structures 102 and 104 may be electrically connected to the peripheral circuit element PT.

Referring to FIG. 9, in the third direction Z, the upper surface of the first dam structure 166 may be disposed on the first surface 201_1 of the etching stop film 201, and the upper surface of the second dam structure 168 may be disposed at a different level from the second surface 201_2 of the etching stop film 201 In the third direction Z, the first dam structure 166 may not penetrate through the etching stop film 201. The second dam structure 168 may extend into (e.g., penetrate through) the etching stop film 201 and the third interlayer insulating film 202 and be in contact with the first metal wiring 262 in (within) the fourth interlayer insulating film 203.

Each of the third and fourth interlayer insulating films 202 and 203 may include, for example, silicon, silicon oxide, silicon nitride, silicon oxynitride, and/or silicon carbide, but is not limited thereto.

Meanwhile, referring to FIG. 9, the first dam structure 166 may be (electrically) connected to the peripheral wiring structure 260 (electrically) connected to the source/drain region 204. The second dam structure 168 may be (electrically) connected to the peripheral wiring structure 260 connected to the peripheral element isolation film 205.

Referring to FIG. 10, in the third direction Z, the upper surface of the first dam structure 166 may be disposed at a different level from the second surface 201_2 of the etching stop film 201, and the upper surface of the second dam structure 168 may be in contact with the lower surface of the mold sacrificial film 117. In the third direction Z, the first dam structure 166 may extend into (e.g., penetrate through) the etching stop film 201 and the third interlayer insulating film 202 and be in contact with the second metal wiring 261 in (within) the fourth interlayer insulating film 203. The second dam structure 168 may not penetrate through (may not extend into) the etching stop film 201.

Meanwhile, referring to FIG. 10, the first dam structure 166 may be (electrically) connected to the peripheral wiring structure 260 connected to the peripheral element isolation film 205. The second dam structure 168 may be (electrically) connected to the peripheral wiring structure 260 (electrically) connected to the source/drain region 204.

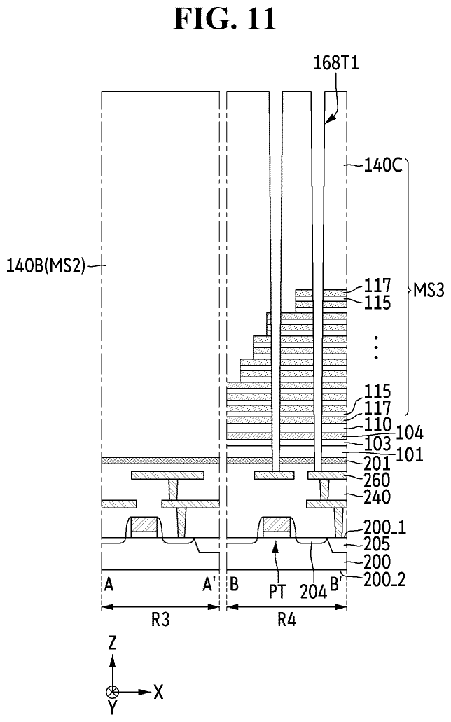

FIGS. 11 to 15 are intermediate step views for describing a method for manufacturing a semiconductor memory device according to some example embodiments. For convenience of explanation, points different from those described with reference to FIGS. 1 to 8 will be mainly described.

Referring to FIG. 11, a peripheral circuit element PT and a peripheral wiring structure 260 may be formed on (in) a peripheral circuit board 200. The peripheral circuit element PT and the peripheral wiring structure 260 may be formed in (within) an inter-wiring insulating film 240 on the peripheral circuit board 200. An etching stop film 201 may be formed on the inter-wiring insulating film 240, and an insulating substrate 101 may be formed on the etching stop film 201.

In a third region R3, a second mold structure MS2 including a second insulating film 140B may be formed.

In a fourth region R4, a third mold structure MS3 including a plurality of mold sacrificial films 117, a plurality of mold insulating films 110 and 115, and a third insulating film 140C may be formed.

In the fourth region R4, a first trench 168T1 extending in the third direction Z may be formed in (within) the third insulating film 140C, the plurality of mold sacrificial films 117, and the plurality of mold insulating films 110 and 115. The first trench 168T1 may further extend into (e.g., penetrate through) the etching stop film 201 to expose an upper surface of the peripheral wiring structure 260.

Although not specifically illustrated, a mask (not illustrated) may be formed on the second mold structure MS2 of the third region R3. Through the mask (not illustrated), a first trench 168T1, a sacrificial material layer 168P described later, and a second trench 168T2 may be selectively formed in the fourth region R4.

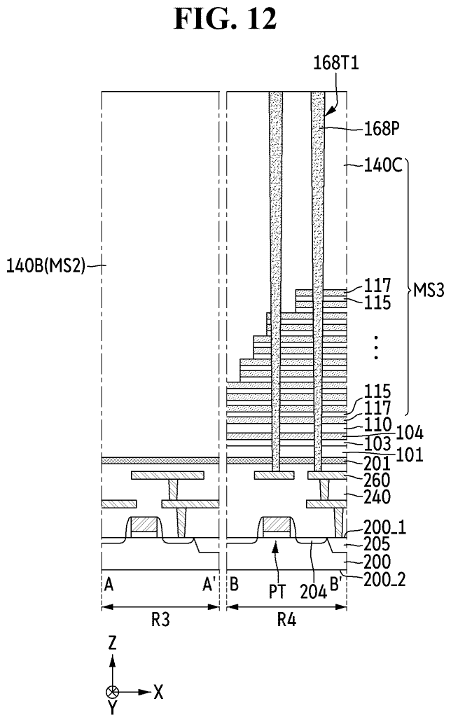

Referring to FIG. 12, a sacrificial material layer 168P may be formed in (within) the first trench 168T1. For example, the sacrificial material layer 168P may include polysilicon that is not doped with carbon and/or impurities. Although not specifically illustrated, during the process of forming the sacrificial material layer 168P, a seam structure may be formed in (within) the sacrificial material layer 168P, but is not limited thereto.

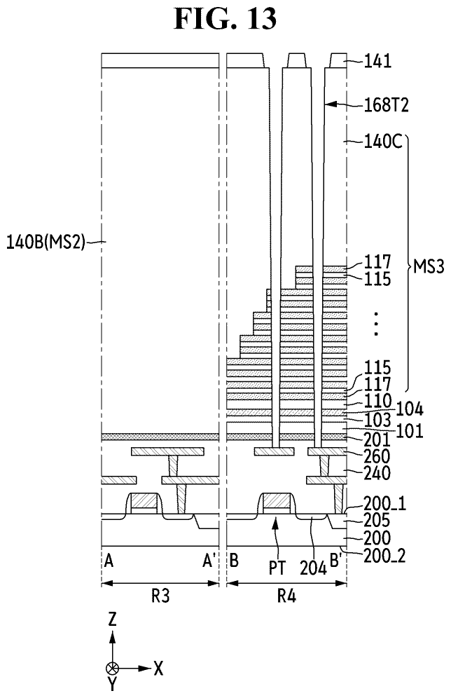

Referring to FIG. 13, the sacrificial material layer 168P may be removed. A first interlayer insulating film 141 may be formed on the second and third mold structures MS2 and MS3. Thereafter, a second trench 168T2 extending in the third direction Z may be formed in (within) the first interlayer insulating film 141, the third mold structure MS3, and the etching stop film 201. A profile of an upper region of the second trench 168T2 formed in (within) the first interlayer insulating film 141 may be different from a profile of a lower region of the second trench 168T2 formed in (within) the third mold structure MS3.

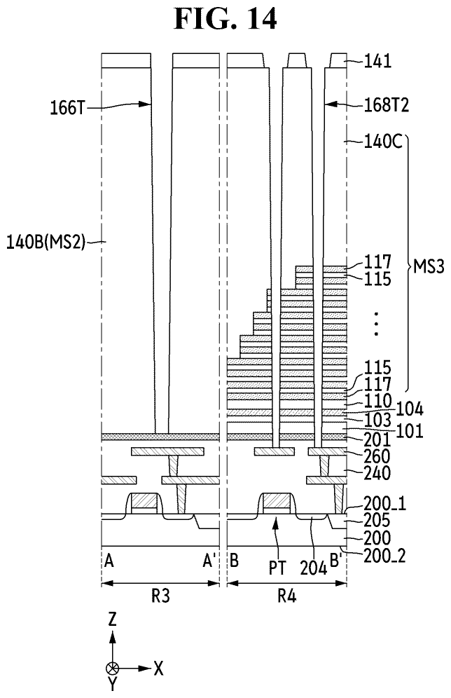

Referring to FIG. 14, the mask (not illustrated) of the third region R3 may be removed. Thereafter, a third trench 166T extending in the third direction Z may be formed in (within) the second mold structure MS2. The third trench 166T may not penetrate through (may not extend into) the etching stop film 201. The third trench 166T may expose an upper surface of the etching stop film 201.

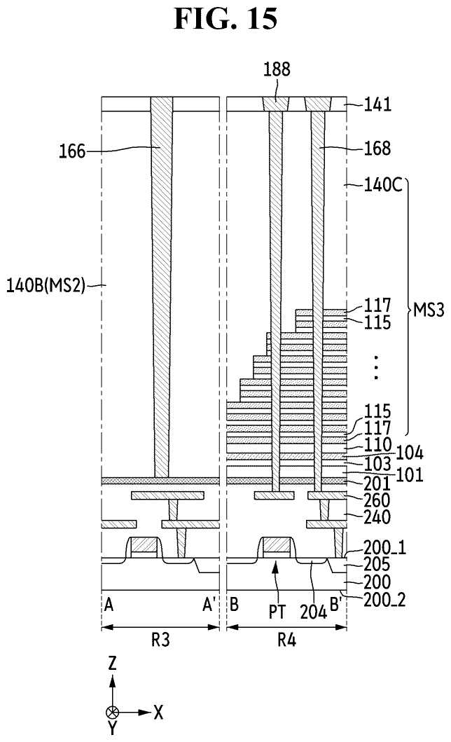

Referring to FIG. 15, a conductive material may be (at least partially) filled in the third trench 166T to form a first dam structure 166. A conductive material may be (at least partially) filled in the second trench 168T2 within the third mold structure MS3 to form a second dam structure 168. A conductive material may be (at least partially) filled in the second trench 168T2 in (within) the first interlayer insulating film 141 to form a second wiring line 188. The second dam structure 168 and the second wiring line 188 may be formed integrally with each other.

Through such processes, the semiconductor memory device described with reference to FIG. 5 may be formed.

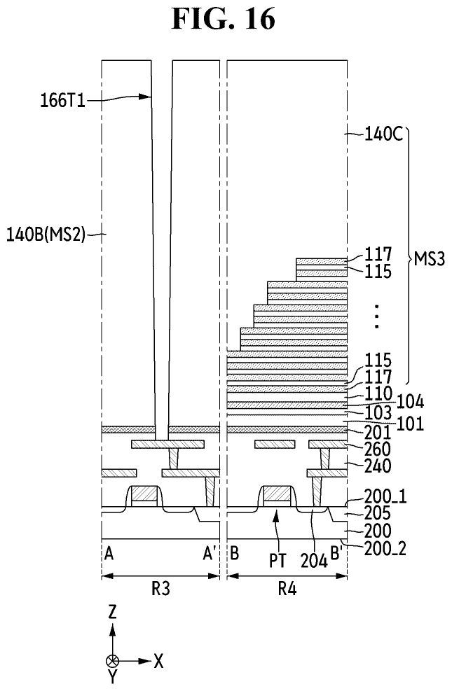

FIGS. 16 to 20 are intermediate step views for describing a method for manufacturing a semiconductor memory device according to some example embodiments. For convenience of explanation, points different from those described with reference to FIGS. 1 to 15 will be mainly described.

In a third region R3, a second mold structure MS2 including a second insulating film 140B may be formed.

In a fourth region R4, a third mold structure MS3 including a plurality of mold sacrificial films 117, a plurality of mold insulating films 110 and 115, and a third insulating film 140C may be formed.

In the third region R3, a first trench 166T1 extending in the third direction Z may be formed in (within) the second insulating film 140B. The first trench 166T1 may further extend into (e.g., penetrate through) the etching stop film 201 to expose an upper surface of the peripheral wiring structure 260.

Although not specifically illustrated, a mask (not illustrated) may be formed on the third mold structure MS3 of the fourth region R4. Through the mask (not illustrated), a first trench 166T1, a sacrificial material layer 166P described later, and a second trench 166T2 may be selectively formed in the third region R3.

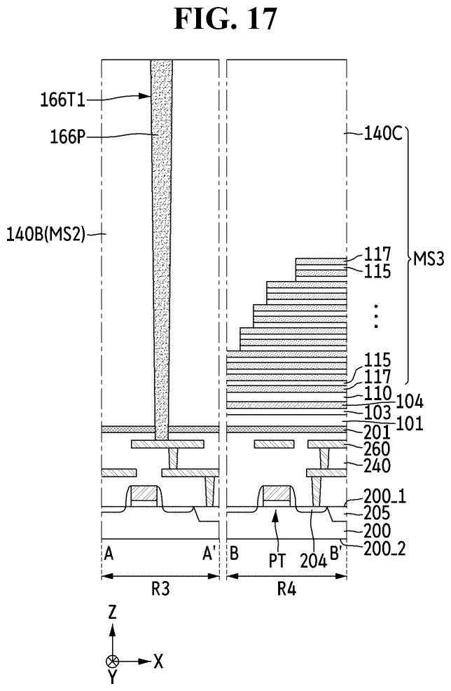

Referring to FIG. 17, a sacrificial material layer 166P may be formed in (within) the first trench 166T1. For example, the sacrificial material layer 166P may include polysilicon that is not doped with carbon and/or impurities. Although not specifically illustrated, during the process of forming the sacrificial material layer 166P, a seam structure may be formed in (within) the sacrificial material layer 166P, but is not limited thereto.

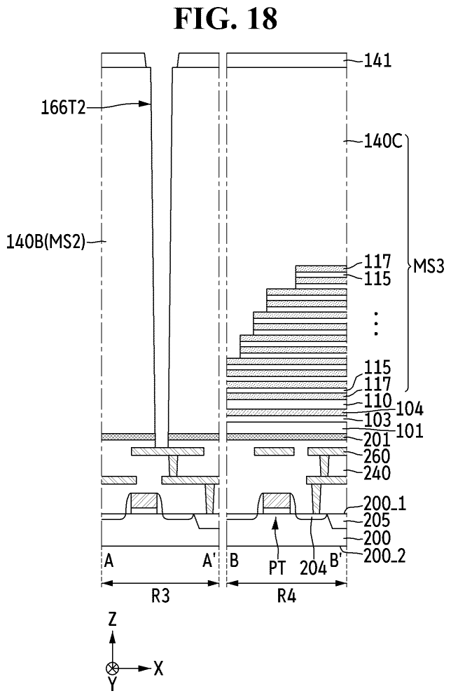

Referring to FIG. 18, the sacrificial material layer 166P may be removed. A first interlayer insulating film 141 may be formed on the second and third mold structures MS2 and MS3. Thereafter, a second trench 166T2 extending in the third direction Z may be formed in (within) the first interlayer insulating film 141, the second mold structure MS2, and the etching stop film 201. A profile of an upper region of the second trench 166T2 formed in (within) the first interlayer insulating film 141 may be different from a profile of a lower region of the second trench 166T2 formed in (within) the second mold structure MS2.

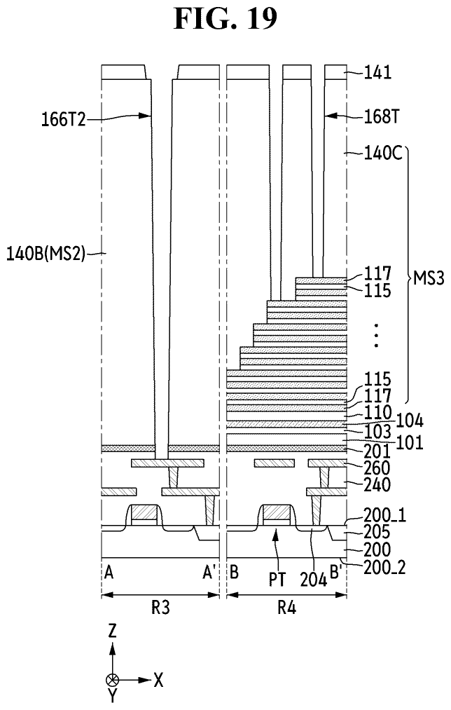

Referring to FIG. 19, the mask (not illustrated) of the fourth region R4 may be removed. Thereafter, a third trench 168T extending in the third direction Z may be formed in (within) the third mold structure MS3. The third trench 168T may not penetrate through (may not extend into) the etching stop film 201. The third trench 168T may expose an upper surface of the uppermost mold sacrificial film among the mold sacrificial films 117.

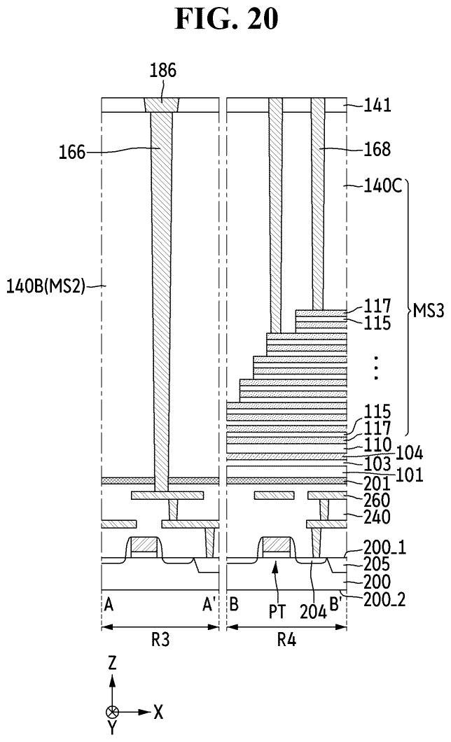

Referring to FIG. 20, a conductive material may be (at least partially) filled in the second trench 166T2 within the second mold structure MS2 to form a first dam structure 166. A conductive material may be (at least partially) filled in the second trench 166T2 within the first interlayer insulating film 141 to form a fifth wiring line 186. A conductive material may be (at least partially) filled in the third trench 168T to form a second dam structure 168. The first dam structure 166 and the fifth wiring line 186 may be formed integrally with each other.

Through such processes, the semiconductor memory device described with reference to FIG. 8 may be formed.

As described above, the first and second dam structures 166 and 168 may be formed within the second and third mold structures MS2 and MS3, respectively. The first and second dam structures 166 and 168 may be formed to prevent a propagation of cracks that may occur during chip cutting at the periphery of the memory region MEM and to prevent moisture from permeating into the chip.

In some example embodiments, the first dam structure 166 and the second dam structure 168 at the periphery of the memory region MEM may each be formed through separate patterning processes. Accordingly, defects caused by crack generation and residual materials that may occur during the process of forming the dam structure may be minimized.

Hereinafter, an electronic system including the semiconductor memory device according to the example embodiments will be described.

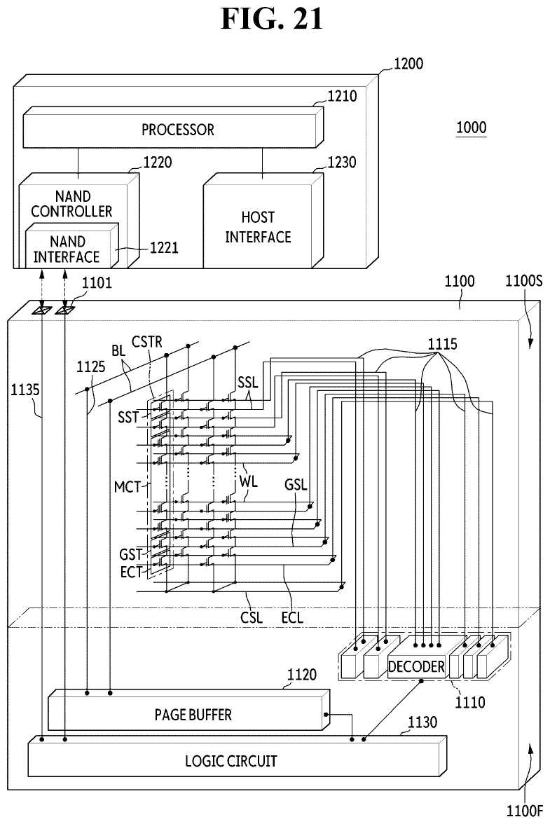

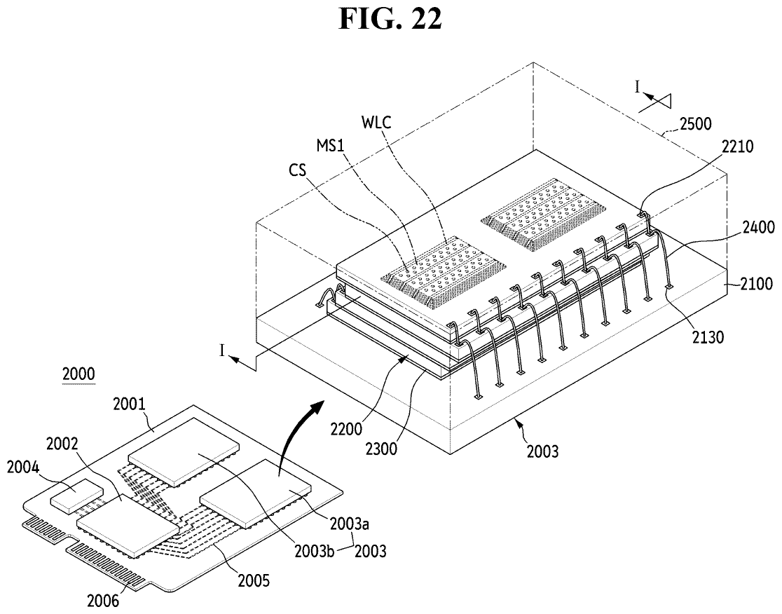

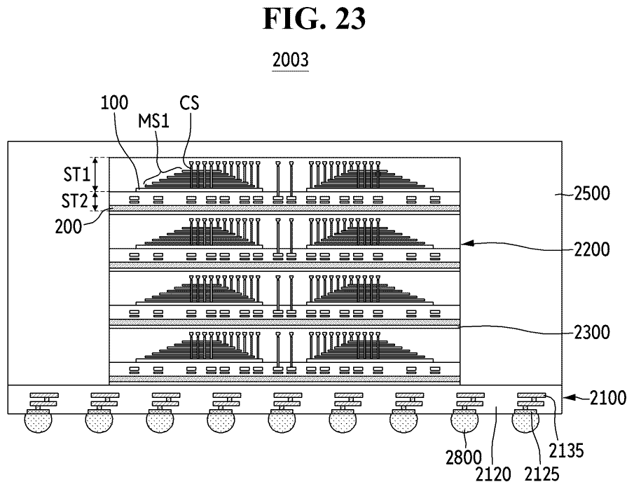

FIG. 21 is an example block diagram for describing an electronic system according to some example embodiments. FIG. 22 is an example perspective view for describing an electronic system according to some example embodiments. FIG. 23 is a schematic cross-sectional view taken along line I-I of FIG. 22. For convenience of explanation, portions overlapping those described above with reference to FIGS. 1 to 20 will be briefly described or omitted.

Referring to FIG. 21, an electronic system 1000 according to some example embodiments may include a semiconductor memory device 1100 and a controller 1200 electrically connected to the semiconductor memory device 1100. The electronic system 1000 may be a storage device including one semiconductor memory device 1100 or a plurality of semiconductor memory devices 1100 or an electronic device including the storage device. For example, the electronic system 1000 may be a solid state drive (SSD) device, a universal serial bus (USB), a computing system, a medical device, or a communication device including one semiconductor memory device 1100 or a plurality of semiconductor memory devices 1100.

The semiconductor memory device 1100 may be, for example, a NAND flash memory device, and may be, for example, the semiconductor memory device described above with reference to FIGS. 5, 8, 9, and/or 10. The semiconductor memory device 1100 may include a first structure 1100F and a second structure 1100S on the first structure 1100F.

The first structure 1100F may be a peripheral circuit structure including a decoder circuit 1110 (e.g., a row decoder 33 in FIG. 1), a page buffer 1120 (e.g., a page buffer 35 in FIG. 1), and a logic circuit 1130 (e.g., a control logic 37 in FIG. 1).

The second structure 1100S may include the common source line CSL, the plurality of bit lines BL, and the plurality of cell strings CSTR described above with reference to FIG. 2. The cell strings CSTR may be (electrically) connected to the decoder circuit 1110 through the word line WL, at least one string select line SSL, and at least one ground select line GSL. In addition, the cell strings CSTR may be (electrically) connected to the page buffer 1120 through the bit lines BL.

In some example embodiments, the common source line CSL and cell string CSTR may be electrically connected to the decoder circuit 1110 through first connection wirings 1115 extending between the first structure 1100F and the second structure 1100S.

In some example embodiments, the bit lines BL may be electrically connected to the page buffer 1120 through second connection wirings 1125 extending between the first structure 1100F and the second structure 1100S.

The semiconductor memory device 1100 may communicate with the controller 1200 through an input/output pad 1101 electrically connected to the logic circuit 1130 (e.g., the control logic 37 in FIG. 1). The input/output pad 1101 may be electrically connected to the logic circuit 1130 through an input/output connection wiring 1135 extending between the first structure 1100F and the second structure 1100S.

The controller 1200 may include a processor 1210, a NAND controller 1220, and a host interface 1230. In some example embodiments, the electronic system 1000 may include a plurality of semiconductor memory devices 1100, and in this case, the controller 1200 may control the plurality of semiconductor memory devices 1100.

The processor 1210 may control an overall operation of the electronic system 1000 including the controller 1200. The processor 1210 may operate according to predetermined firmware, and may access the semiconductor memory device 1100 by controlling the NAND controller 1220. The NAND controller 1220 may include a NAND interface 1221 that processes communication with the semiconductor memory device 1100. A control command for controlling the semiconductor memory device 1100, data to be written to memory cell transistors MCT of the semiconductor memory device 1100, data to be read from the memory cell transistors MCT of the semiconductor memory device 1100, etc. may be transmitted through the NAND interface 1221. The host interface 1230 may provide a communication function between the electronic system 1000 and an external host. When a control command is received from the external host through the host interface 1230, the processor 1210 may control the semiconductor memory device 1100 in response to the control command.

Referring to FIGS. 22 and 23, an electronic system 2000 according to some example embodiments may include a main board 2001, and a main controller 2002, one or more semiconductor packages 2003, and a dynamic random access memory (DRAM) 2004 that are mounted on the main board 2001. The semiconductor package 2003 and the DRAM 2004 may be (electrically) connected to the main controller 2002 by wiring patterns 2005 formed on the main board 2001.

The main board 2001 may include a connector 2006 including a plurality of pins coupled to the external host. The number and arrangement of the plurality of pins in the connector 2006 may vary depending on a communication interface between an electronic system 2000 and the external host. In some example embodiments, the electronic system 2000 may communicate with the external host according to any one of interfaces such as universal serial bus (USB), peripheral component interconnect express (PCI-Express), serial advanced technology attachment (SATA), and M-Phy for universal flash storage (UFS). In some example embodiments, the electronic system 2000 may operate by power supplied from the external host through the connector 2006. The electronic system 2000 may further include a power management integrated circuit (PMIC) for distributing the power supplied from the external host to the main controller 2002 and the semiconductor package 2003.

The main controller 2002 may write or read data to or from the semiconductor package 2003, and may improve an operation speed of the electronic system 2000.

The DRAM 2004 may be a buffer memory for alleviating a speed difference between the semiconductor package 2003, which is a data storage space, and the external host. The DRAM 2004 included in the electronic system 2000 may operate as a kind of cache memory, and may also provide a space for temporarily storing data in a control operation for the semiconductor package 2003. When the electronic system 2000 includes the DRAM 2004, the main controller 2002 may further include a DRAM controller for controlling the DRAM 2004, in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. The first and second semiconductor packages 2003a and 2003b may each include a package substrate 2100, semiconductor chips 2200 on the package substrate 2100, adhesive layers 2300 disposed on a lower surface of each of the semiconductor chips 2200, connection structures 2400 electrically connecting the semiconductor chips 2200 to the package substrate 2100, and a molding layer 2500 on (e.g., covering or overlapping) the semiconductor chips 2200 and the connection structures 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 21.

In some example embodiments, the connection structure 2400 may be a bonding wire electrically connecting the input/output pad 2210 to the package upper pads 2130. Accordingly, in each of the first and second semiconductor packages 2003a and 2003b, the semiconductor chips 2200 may be electrically connected to each other by a bonding wire method, and be electrically connected to the package upper pads 2130 of the package substrate 2100. In some example embodiments, in each of the first and second semiconductor packages 2003a and 2003b, the semiconductor chips 2200 may also be electrically connected to each other by connection structures including through silicon vias (TSVs) instead of the connection structures 2400 of the bonding wire method.

In some example embodiments, the main controller 2002 and the semiconductor chips 2200 may also be included in one package. In some example embodiments, the main controller 2002 and the semiconductor chips 2200 may be mounted on a separate interposer substrate different from the main board 2001, and the main controller 2002 and the semiconductor chips 2200 may also be (electrically) connected to each other by wirings formed on the interposer substrate.

In some example embodiments, the package substrate 2100 may be a printed circuit board. The package substrate 2100 may include a package substrate body portion 2120, package upper pads 2130 disposed on an upper surface of the package substrate body portion 2120, lower pads 2125 disposed on or exposed through a lower surface of the package substrate body portion 2120, and internal wirings 2135 electrically connecting the package upper pads 2130 and the lower pads 2125 to each other in the package substrate body portion 2120. The package upper pads 2130 may be electrically connected to the connection structures 2400. The lower pads 2125 may be (electrically) connected to the wiring patterns 2005 of the main board 2001 of the electronic system 2000 through conductive connectors 2800.

Referring to FIGS. 22 and 23, in the electronic system according to some example embodiments, each of the semiconductor chips 2200 may include the semiconductor memory device described above with reference to FIGS. 5, 8, 9, and/or 10. For example, each of the semiconductor chips 2200 may include the second structure ST2 and the first structure ST1 stacked on the second structure ST2. For example, the first structure ST1 may include the cell substrate 100 and the insulating substrate 101, the first mold structure MS1, the channel structure CS, the source structures 102 and 104, the second mold structure MS2, the first dam structure 166, the third mold structure MS3, the second dam structure 168, the first interlayer insulating film 141, and the etching stop film 201 described above with reference to FIGS. 5, 8, 9, and/or 10. In addition, for example, the second structure may include the peripheral circuit board 200 and the peripheral wiring structure 260 described above with reference to FIGS. 5, 8, 9, and/or 10.

The example embodiments of the present disclosure have been described hereinabove with reference to the accompanying drawings, but it will be understood by one of ordinary skill in the art to which the present disclosure pertains that various modifications and alterations may be made without departing from the features and scopes of the present disclosure. Therefore, it should be understood that the example embodiments described above are illustrative in all aspects and not restrictive.

What is claimed is:

1. A semiconductor memory device comprising:
a first substrate that includes a first region, a second region, and a third region, wherein the second region is adjacent the first region and the third region;
a first mold structure that includes insulating layers and gate electrode layers that are alternately stacked on a first surface of the first substrate in the first region;
a second mold structure on the first surface of the first substrate in the second region;
a third mold structure on the first surface of the first substrate in the third region;
a channel structure that extends into the first mold structure in a first direction that is perpendicular to the first surface of the first substrate;
a first dam structure that extends into the second mold structure in the first direction;
a second dam structure that extends into the third mold structure in the first direction; and
an etching stop film on a second surface of the first substrate that is opposite to the first surface of the first substrate in the first direction,
wherein the etching stop film includes a third surface that is in contact with the second surface of the first substrate and a fourth surface that is opposite to the third surface in the first direction, and
wherein a lower surface of the first dam structure is on the third surface of the etching stop film, and a lower surface of the second dam structure is spaced apart from the fourth surface of the etching stop film in the first direction.

2. The semiconductor memory device of claim 1, wherein the second dam structure penetrates through the etching stop film.

3. The semiconductor memory device of claim 1, further comprising:
an interlayer insulating film on the first mold structure, the second mold structure, and the third mold structure; and
a bit line contact that extends into the interlayer insulating film and is electrically connected to an upper portion of the channel structure.

4. The semiconductor memory device of claim 3, further comprising:
a first wiring line in the interlayer insulating film,
wherein the first dam structure partially extends into the second mold structure,
wherein the second dam structure penetrates through the third mold structure,
wherein the first wiring line is electrically connected to the second dam structure, and
wherein a width of a lower surface of the first wiring line is greater than a width of an upper surface of the second dam structure.

5. The semiconductor memory device of claim 3, further comprising:
a first wiring line in the interlayer insulating film,
wherein the first dam structure penetrates through the second mold structure,
wherein the second dam structure penetrates through the third mold structure,
wherein the first wiring line that is electrically connected to the second dam structure, and
wherein a width of a lower surface of the first wiring line is greater than a width of an upper surface of the second dam structure.

6. The semiconductor memory device of claim 1, further comprising:
a second substrate on the etching stop film, wherein the second substrate includes a fifth surface that faces the second surface of the first substrate and a sixth surface that is opposite to the first surface in the first direction; and
a peripheral wiring structure between the etching stop film and the second substrate in the first direction,
wherein the peripheral wiring structure includes a peripheral element isolation film, peripheral wirings, and peripheral circuit elements, and
wherein the peripheral element isolation film is adjacent at least one of the peripheral circuit elements and/or at least one of the peripheral wirings.

7. The semiconductor memory device of claim 6, wherein the first dam structure penetrates through the second mold structure,
wherein the second dam structure penetrates through the third mold structure, and
wherein the first dam structure is spaced apart from the peripheral wirings in the first direction, and
wherein the second dam structure is electrically connected to at least one of the peripheral wirings.

8. The semiconductor memory device of claim 6, wherein the first dam structure partially extends into the second mold structure,
wherein the second dam structure penetrates through the third mold structure,
wherein the first dam structure is spaced apart from the peripheral wirings in the first direction, and
wherein the second dam structure is electrically connected to at least one of the peripheral wirings.

9. The semiconductor memory device of claim 1, wherein the second mold structure includes a first material, and the third mold structure includes a second material,
wherein the first material has an etch selectivity with respect to the second material.

10. The semiconductor memory device of claim 9, wherein the first material is an oxide, and
wherein the second material is a nitride.

11. The semiconductor memory device of claim 1, wherein the etching stop film includes a nitride.

12. A semiconductor memory device comprising:
a first substrate that includes a first region, a second region, and a third region, wherein the second region is adjacent the first region and the third region;
a first mold structure that includes insulating layers and gate electrode layers that are alternately stacked on a first surface of the first substrate in the first region;
a second mold structure on the first surface of the first substrate in the second region;
a third mold structure on the first surface of the first substrate in the third region;
a channel structure that extends into the first mold structure in a vertical direction that is perpendicular to the first surface of the first substrate;
a first dam structure that is spaced apart from the channel structure in a horizontal direction that is parallel with the first surface of the first substrate, wherein the first dam structure extends into the second mold structure in the vertical direction, in the second region;
a second dam structure that is spaced apart from the first dam structure in the horizontal direction, wherein the second dam structure extends into the third mold structure in the vertical direction, in the third region; and
a second substrate on a second surface of the first substrate that is opposite to the first surface of the first substrate in the vertical direction,
wherein the second substrate includes peripheral circuit elements, a peripheral wiring structure on the peripheral circuit elements, and a peripheral element isolation film that is adjacent at least one of the peripheral circuit elements and/or the peripheral wiring structure,
wherein the peripheral wiring structure includes a first peripheral wiring that is electrically connected to at least one of the peripheral circuit elements and a second peripheral wiring that is connected to the peripheral element isolation film, and
wherein at least one of the first dam structure and the second dam structure is electrically connected to the second peripheral wiring.

13. The semiconductor memory device of claim 12, wherein the first dam structure is electrically separated from the first peripheral wiring, and
wherein the second dam structure is electrically connected to the second peripheral wiring.

14. The semiconductor memory device of claim 12, further comprising:
an etching stop film between the first substrate and the second substrate,
wherein the first dam structure is free of having overlap with the etching stop film in the horizontal direction, and
wherein the second dam structure extends into the etching stop film.

15. The semiconductor memory device of claim 14, wherein the second mold structure includes an oxide layer and a nitride layer,
wherein a lower surface of the first dam structure is in contact with an upper surface of the nitride layer, and
wherein a lower surface of the second dam structure is in contact with the second peripheral wiring.

16. The semiconductor memory device of claim 14, wherein a lower surface of the first dam structure is in contact with an upper surface of the etching stop film, and
wherein a lower surface of the second dam structure is in contact with the second peripheral wiring.

17. The semiconductor memory device of claim 12, wherein the first dam structure includes a first conductive material, and
wherein the second dam structure includes a second conductive material that is different from the first conductive material.

18. The semiconductor memory device of claim 12, further comprising a source structure that is electrically connected to the channel structure on the first substrate,
wherein the source structure includes polysilicon.

19. An electronic system comprising:
a main board;
a semiconductor memory device that includes a first structure and a second structure that is below the first structure on the main board; and
a controller that is electrically connected to the semiconductor memory device on the main board,
wherein the first structure includes:
a first substrate that includes a first region, a second region, and a third region, wherein the second region and the third region extend around the first region;
a first mold structure that includes insulating layers and gate electrode layers alternately stacked on a first surface of the first substrate in the first region;
a second mold structure that includes an oxide layer on the first surface of the first substrate in the second region;
a third mold structure that includes oxide layers and nitride layers that are alternately stacked on the first surface of the first substrate in the third region;
a channel structure that extends into the first mold structure in a first direction that is perpendicular to the first surface of the first substrate;
a source structure that is electrically connected to a lower portion of the channel structure on the first surface of the first substrate;
a first dam structure that extends into the second mold structure in the first direction;
a second dam structure that at least partially extends into the third mold structure in the first direction;
an interlayer insulating film on the first mold structure, the second mold structure, and the third mold structure;
a bit line contact that extends into the interlayer insulating film and is electrically connected to an upper portion of the channel structure; and
an etching stop film that includes a nitride on a second surface of the first substrate that is opposite to the first surface of the first substrate in the first direction,
wherein the second structure includes:
a second substrate that faces the second surface of the first substrate;
peripheral circuit elements on the second substrate;
a first peripheral wiring that is electrically connected to at least one of the peripheral circuit elements; and
a second peripheral wiring that is connected to an element isolation film that is adjacent at least one of the peripheral circuit elements and/or the first peripheral wiring,
wherein the first dam structure is free of having overlap with the etching stop film in a second direction that is parallel with the first surface of the first substrate,
wherein the second dam structure extends into the etching stop film,
wherein the first dam structure is spaced apart from the first peripheral wiring, and
wherein the second dam structure is in contact with the second peripheral wiring.

20. The electronic system of claim 19, further comprising:
a first wiring line on the first dam structure; and
a second wiring line on the second dam structure,
wherein a width of a lower surface of the first wiring line is equal to a width of an upper surface of the first dam structure, and
wherein a width of a lower surface of the second wiring line is greater than a width of an upper surface of the second dam structure.
